(19) United States
(12) Patent Application Publication
(10) Pub. No.: US 2015/0171535 A1
(43) Pub. Date: Jun. 18, 2015

(54) MEMORY CONNECTOR FOR TWO SODIMM PER CHANNEL CONFIGURATION

(71) Applicants: Xiang Li, Hillsboro, OR (US); Chong J. Zhao, West Linn, OR (US); Jefferey L. Krieger, Portland, OR (US); Dan Willis, Portland, OR (US); John M. Lynch, Forest Grove, OR (US); Yun Ling, Portland, OR (US)

(72) Inventors: Xiang Li, Hillsboro, OR (US); Chong J. Zhao, West Linn, OR (US); Jefferey L. Krieger, Portland, OR (US); Dan Willis, Portland, OR (US); John M. Lynch, Forest Grove, OR (US); Yun Ling, Portland, OR (US)

(21) Appl. No.: 13/994,023

(22) PCT Filed: Dec. 28, 2011
(86) PCT No.: PCT/US2011/067474

§ 371 Date: Jun. 13, 2013

(51) Int. Cl. H01R 12/73; H05K 1/18

(52) U.S. Cl. CPC H01R 12/732; H05K 1/181; H05K 2201/10159

(57) ABSTRACT

According to some embodiments, a SODIMM memory connector comprises a first socket to electrically couple a first SODIMM, and a second socket to electrically couple a second SODIMM, where the first socket is disposed vertically adjacent to the second socket.

### BACKGROUND OF THE INVENTION

A small outline dual in-line memory module (“SODIMM”) is a type of computer memory. A SODIMM is a smaller memory module than a dual in-line memory module (“DIMM”) being roughly half the size of a regular DIMM and SODIMMS are typically used in systems which have space restrictions such as notebooks, printers, and routers.

In conventional system which use SODIMM modules, a conventional two SODIMM per channel configuration (e.g. connector), as illustrated in FIG. 1A, comprises a first SODIMM socket 101 and a second SODIMM socket 102 where the second SODIMM socket 102 is offset from the first SODIMM socket 101. The first SODIMM socket 101 may be 9.2 mm high and the second SODIMM socket 102 may be 5.2 mm high. A mother board 103, as illustrated in FIG. 1B, thereby requires surface area (i.e., a footprint) large enough to cover the two offset sockets. Furthermore, this offset configuration requires transmission line 104 and vias 105 to connect the first SODIMM socket 101 and the second SODIMM socket 102 in a daisy chain configuration, which may introduce cross talk, attenuation and impedance mismatch, causing signal integrity degradation.

### BRIEF DESCRIPTION OF THE DRAWINGS

FIG. 1A is a perspective view of a conventional SODIMM connector.

FIG. 1B is a cross section of a SODIMM connector.

FIG. 2A is a perspective view of a SODIMM connector according to some embodiments.

FIG. 2B is a cross section of a SODIMM connector according to some embodiments.

FIG. 3A is a cross section of a SODIMM connector according to some embodiments.

FIG. 3B is a cross section of a SODIMM connector according to some embodiments.

FIG. 3C is a cross section of a SODIMM connector according to some embodiments.

FIG. 3D is a perspective view of a SODIMM connector according to some embodiments.

FIG. 4A is a cross section of a SODIMM connector according to some embodiments.

FIG. 4B is a cross section of a SODIMM connector according to some embodiments.

FIG. 4C is a cross section of a SODIMM connector according to some embodiments.

FIG. 4D is a cross section of a SODIMM connector according to some embodiments.

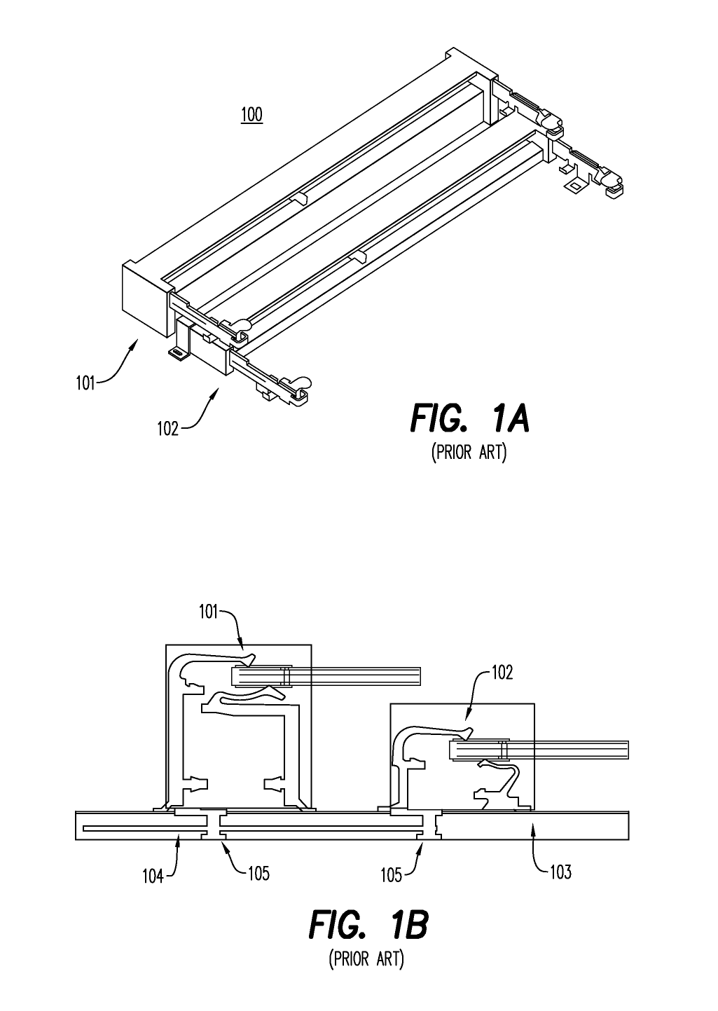

### DETAILED DESCRIPTION OF EXAMPLE EMBODIMENTS

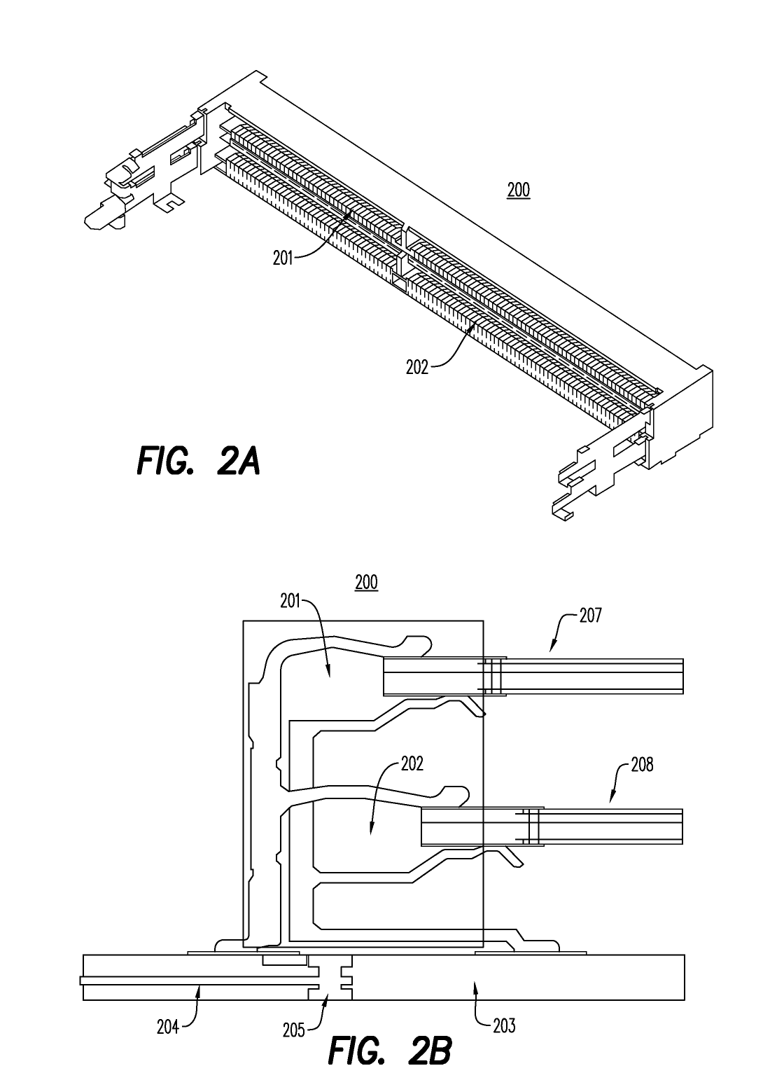

Referring now to FIG. 2A and FIG. 2B, an embodiment of a SODIMM connector 200 is illustrated. The SODIMM connector 200 may support two SODIMMs per one channel (“2DPC”) within a single connector. The SODIMM connector 200 comprises a first socket 201 and a second socket 202. Each socket 201/202 comprises a plurality of pins to electrically couple corresponding gold fingers on a DIMM. A gold finger may comprise an electrical contact on a DIMM. As illustrated, the first socket 201 is vertically adjacent to the second socket 202. The first socket 101 is to electrically couple a first SODIMM 207 and the second socket 202 is to electrically couple a second SODIMM 208. In some embodiments, the SODIMMs 207/208 may comprise small outline double data rate 3 (“SODDR3”) memory modules. However, in other embodiments, the SODIMMs 207/208 may comprise small outline double data rate 4 (“SODDR4”) memory modules.

Sockets to electrically couple SODDR3 memory modules have a plurality of unique pins, some to electrically couple gold fingers on a first surface of the SODDR3 memory module and some to electrically couple gold fingers on a second surface of the SODDR3. Likewise, sockets to electrically couple SODDR4 memory modules have a plurality of unique pins, some to electrically couple gold fingers on a first surface of the SODDR4 memory module and to electrically couple gold fingers on a second surface of the SODDR4. Sockets to electrically couple SODDR4 memory modules may have more unique pins distributed on a first surface compared to DDR3 memory module. Gold fingers associated with unique pins may be aligned differently on a SODIMM than gold fingers associated with non-unique pins and therefore a portion of a SODIMM connector associated with unique pins may be configured differently than a portion of a SODIMM associated with non-unique pins. Unique pins may comprise CLK, CKE, ODT, and CS pins where the CLK pin may relate to a clock, the CKE pin may relate a clock enable signal, the ODT pin may relate to an on-die termination and the CS pin may relate to a chip select. Non-unique pins may relate to DQ, CA, VSS, and VDD pins where DQ pins (also called Input/Output pins or I/Os) may be used for input and output, CA pins may relate to command and address which may be used to latch an address and to initiate a read or write operation, VSS may relate to a ground, and VDD may relate to power/voltage.

The SODIMM connector 200 may to be coupled to a motherboard 203 of a computing device where a SODIMM connector 200 is to receive data (e.g., for a SODIMM coupled to the SODIMM connector 200) through a via 205 that receives the data through a transmission line 204. By using only a single via 205, the present embodiments use less transmission line than the daisy chain configuration disclosed in the prior art embodiments. Using less transmission line may improve signal integrity. Furthermore, the SODIMM connector may comprise a “T” topology configuration, which may provide superior performance than a daisy chain configuration. In some embodiments, each socket 201/202 may comprise six different types of pins to provide connectivity (e.g., to the unique pins and the non-unique pins).

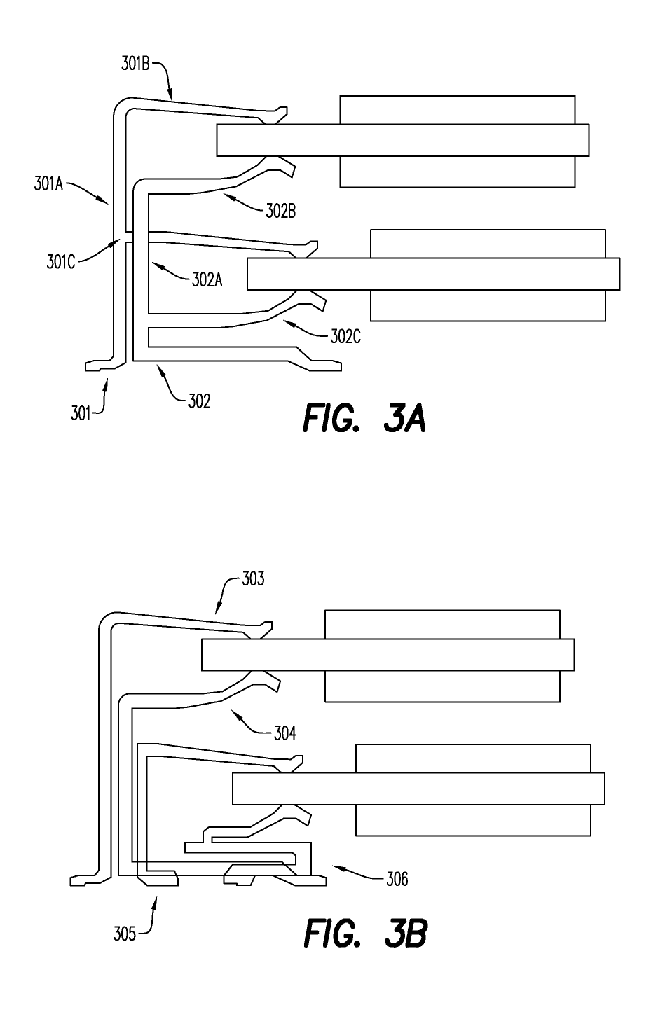

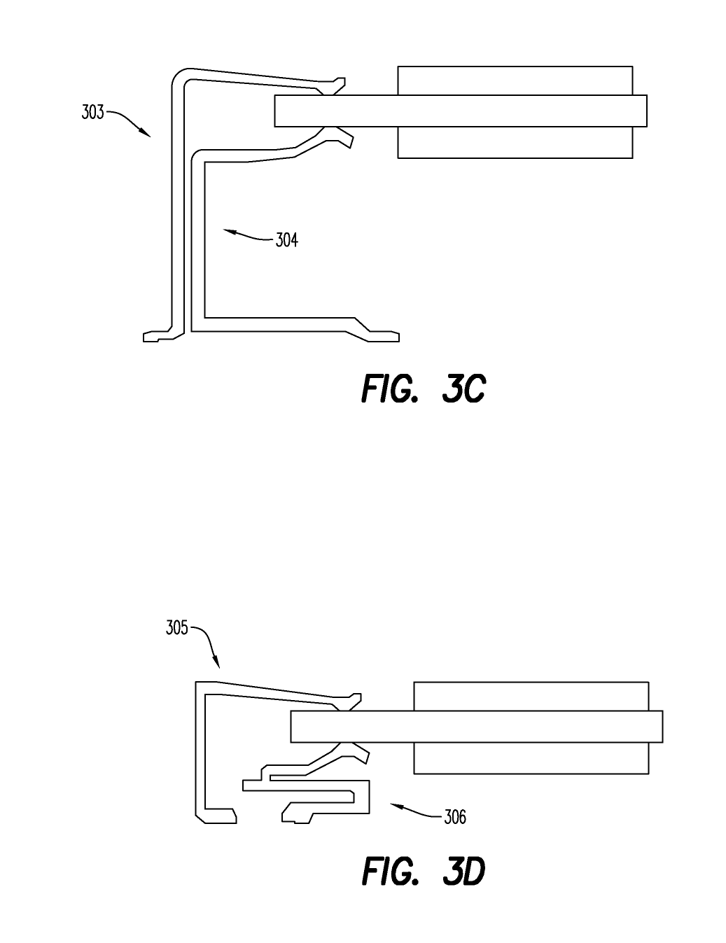

Now referring to FIGS. 3A, 3B, 3C, and 3D an embodiment of a SODIMM connector 300 is illustrated. In some embodiments, FIGS. 3A, 3B, 3C, and 3D may relate to a SODIMM connector 300 that is configured to receive a horizontal insertion of one or more SODIMMs into the SODIMM connector 300. The SODIMM connector 300 may comprise a plurality of portions, including a first portion 301, a second portion 302, a third portion 303, a fourth portion 304, a fifth portion, and a sixth portion 306. Each portion 301/302/303/304/305/306 may be associated with providing one or more types of signals to a first SODIMM and/or a second SODIMM and each portion 301/302/303/304/305/306 may be electrically insulated from each other portion 301/302/303/304/305/306. Furthermore, the SODIMM connector 300 may comprise a plurality of each portion 301/302/303/304/305/306. Each portion 301/302/303/304/305/306 may comprise a plurality of pins that are to be electrically coupled to corresponding gold fingers associated with SODIMMS.

As illustrated in FIG. 3A, the first portion 301 comprises a vertical portion 301A with a substantially horizontal first branch 301B to provide connectivity to a first side of a first SODIMM and a substantially horizontal second branch 301C to provide connectivity to a first side of a second SODIMM. The second portion 302 comprises a vertical portion 302A with a substantially horizontal first branch 302B to provide connectivity to a second side of the first SODIMM and a substantially horizontal second branch 302C to provide connectivity to a second side of the second SODIMM. In some embodiments, the first portion 301 and the second portion 302 are associated with DQ, CA, VSS, and VDD pins.

Now referring to FIG. 3B, the third portion 303, the fourth portion 304, the fifth portion 305 and the sixth portion 306 may be associated with CLK, CKE, ODT, and CS pins. The third portion may comprise a vertical portion connected to a horizontal branch to provide connectivity to the first side of the first SODIMM. The fourth portion 304 may comprise a horizontal vertical portion connected to a horizontal branch to provide connectivity to the second side of the first SODIMM. The fifth portion 305 may comprise a vertical portion connected to a horizontal branch to provide connectivity to the first side of the second SODIMM. The sixth portion 306 may comprise a vertical portion connected to a horizontal branch to provide connectivity to the second side of the second SODIMM. As illustrated, the vertical portion of the third portion 303 has a greater height than the vertical portion of the fourth portion 304, fifth portion 305, and sixth portion 306. Similarly, the vertical portion of the fourth portion 304 has a greater height than the vertical portion of the fifth portion 305, and sixth portion 306 while the fifth portion 305 has a greater height than the vertical portion of the sixth portion 306.

In some embodiments, the SODIMM connector 300 may be one SODIMM per channel (“1DPC”) compatible, meaning that if the SODIMM connector 300 is used on a motherboard having a regular DDR3/DDR4 footprint, a top socket of the SODIMM connector 300 may function like a conventional DDR3/DDR4 SODIMM connector. In some embodiments where only a single SODIMM is required, the SODIMM connector 300 may be configured to electrically couple a single SODIMM. As illustrated in FIG. 3C third portion 303 and fourth portion 304 may be used to provide connectivity to gold fingers associated with unique pins without a fifth or sixth portion. Similarly, FIG. 3D illustrates another embodiment where a single SODIMM is used and the firth portion 305 and sixth portion 306 are used to provide connectivity to gold fingers associated with the unique pins without a first or second portion. As illustrated, each embodiment, 3C or 3D, may associated with a height of the SODIMM connector 300.

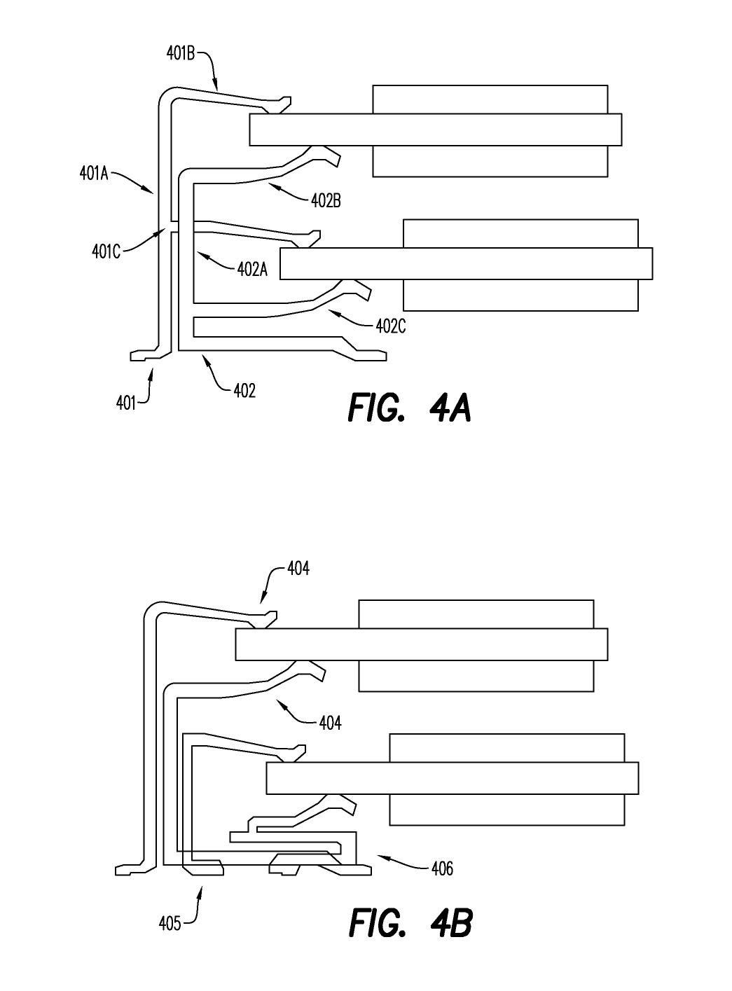

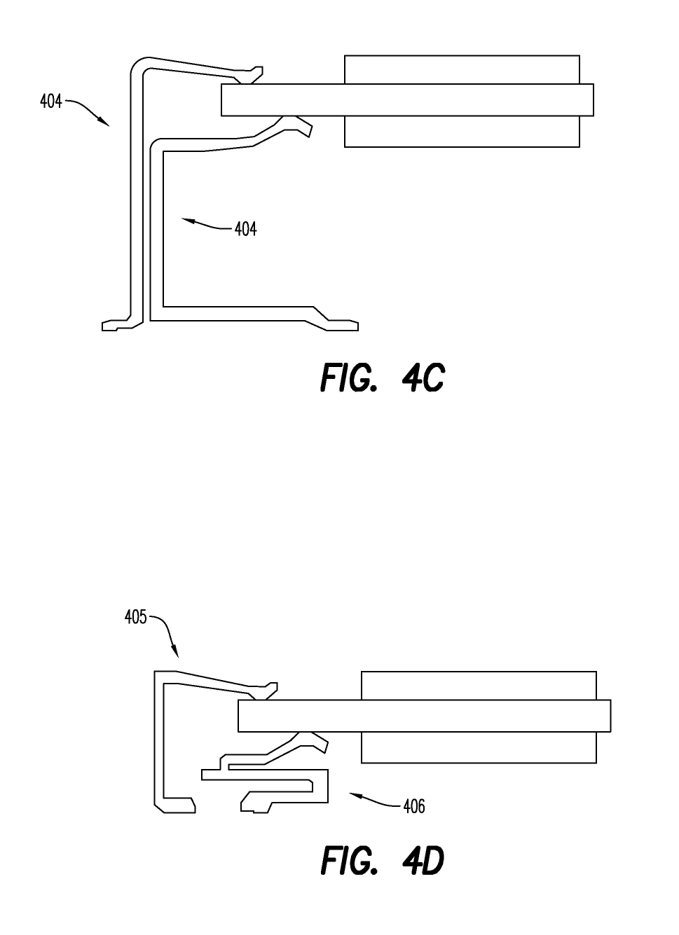

Now referring to FIGS. 4A, 4B, 4C, and 4D, an embodiment of a SODIMM connector 400 is illustrated. In some embodiments, FIGS. 4A, 4B, 4C, and 4D may relate to a SODIMM connector 400 capable of receiving an angled insertion of one or more SODIMMs. Similar to the SODIMM connector 300, the SODIMM connector 400 may comprise a plurality of portions, including a first portion 401, a second portion 402, a third portion 403, a fourth portion 404, a fifth portion 405 and a sixth portion 406. Each portion 403/404/405/406 may be associated with providing one or more types of signals to a first SODIMM and/or a second SODIMM and each portion 401/402/403/404/405/406 being electrically insulated from each other. Furthermore, the SODIMM connector 400 may comprise a plurality of each portion 401/402/403/404/405/406.

As illustrated in FIG. 4A, the first portion 401 comprises a vertical portion 401A with a substantially horizontal first branch 401B to provide connectivity to a first side of a first SODIMM and a substantially horizontal second branch 401C to provide connectivity to a first side of a second SODIMM. The second portion 402 comprises a vertical portion 402A with a substantially horizontal first branch 402B to provide connectivity to a second side of the first SODIMM and a substantially horizontal second branch 402C to provide connectivity to a second side of the second SODIMM. In some embodiments, the first portion 401 and the second portion 402 are associated with non-unique pins. To facilitate an angled insertion, the first horizontal branch 401B of the first portion 401 may have a shorter length than the first horizontal branch 402B of the second portion 402. Likewise, the second horizontal branch 401C of the first portion 401 may have a shorter length than the second horizontal branch 402C of the second portion 402.

Now referring to FIG. 4B, the third portion 403, the fourth portion 404, the fifth portion 405 and the sixth portion 406 may be associated with unique pins. The third portion 403 may comprise a vertical portion connected to a horizontal branch to provide connectivity to the first side of the first SODIMM. The fourth portion 404 may comprise a horizontal vertical portion connected to a horizontal branch to provide connectivity to the second side of the first SODIMM. The fifth portion 405 may comprise a vertical portion connected to a horizontal branch to provide connectivity to the first side of the second SODIMM. The sixth portion 406 may comprise a vertical portion connected to a horizontal branch to provide connectivity to the second side of the second SODIMM. As illustrated, the vertical portion of the third portion 403 has a greater height than the vertical portion of the fourth portion 404, fifth portion 405, and sixth portion 406. Similarly, the vertical portion of the fourth portion 404 has a greater height than the vertical portion of the fifth portion 405, and sixth portion 406 while the fifth portion 405 has a greater height than the vertical portion of the sixth portion 406. To facilitate an angled insertion, the horizontal branch of the third portion may be shorter than the horizontal branch of the fourth portion.

In some embodiments where only a single SODIMM is required, the SODIMM connector 400 may comprise a single SODIMM. As illustrated in FIG. 4C third portion 403 and fourth portion 404 may be used to provide connectivity to unique pins without a fifth or sixth portion. Similarly, FIG. 4D illustrates another embodiment where a single SODIMM is used and the fifth portion 405 and sixth portion 406 are used to provide connectivity to the unique pins without a first or second portion. As illustrated, each embodiment, 4C or 4D, may be associated with a height of the connector 400.

Various modifications and changes may be made to the foregoing embodiments without departing from the broader spirit and scope set forth in the appended claims.

What is claimed is:

1. A SODIMM memory connector comprising:
a first socket to electrically couple a first SODIMM; and
a second socket to electrically couple a second SODIMM, where the first socket is disposed vertically adjacent to the second socket.

2. The SODIMM memory connector of claim 1, wherein the connector comprises:
a first portion to provide connectivity to a first gold finger on a first side of a first SODIMM and to provide connectivity to a first gold finger on a first side of a second SODIMM; and
a second portion to provide connectivity to a first gold finger on a second side of the first SODIMM and to provide connectivity to a first gold finger on the second side of the second SODIMM.

3. The SODIMM memory connector of claim 2, wherein the connector further comprises:
a third portion to provide connectivity to a second gold finger on the first side of the first SODIMM;
a fourth portion to provide connectivity to a second gold finger on the second side of the first SODIMM;
a fifth portion to provide connectivity to a second gold finger on the first side of the second SODIMM; and
a sixth portion to provide connectivity to a second gold finger on the second side of the second SODIMM.

4. The SODIMM memory connector of claim 3, wherein the first portion and the second portion are associated with DQ, CA, VSS, and VDD pins.

5. The SODIMM memory connector of claim 3, wherein the third portion, fourth portion, fifth portion and the sixth portion are associated with CLK, CKE, ODT, and CS pins.

6. The SODIMM memory connector of claim 1 wherein the first SODIMM and the second SODIMM are SODDR3 memory modules.

7. The SODIMM memory connector of claim 1 wherein the first SODIMM and the second SODIMM are SODDR4 memory modules.

8. An apparatus comprising:
a motherboard; and
a SODIMM memory connector coupled to the motherboard, the SODIMM memory connector comprising:
a first socket to electrically couple a first SODIMM; and
a second socket to electrically couple a second SODIMM, where the first socket is disposed vertically adjacent to the second socket.

9. The apparatus of claim 8, wherein the SODIMM memory connector comprises:
a first portion to provide connectivity to a first gold finger on a first side of a first SODIMM and to provide connectivity to a first gold finger on a first side of a second SODIMM; and
a second portion to provide connectivity to a first gold finger on a second side of the first SODIMM and to provide connectivity to a first gold finger on the second side of the second SODIMM.

10. The apparatus of claim 9, wherein the SODIMM memory connector further comprises:
a third portion to provide connectivity to a second gold finger on the first side of the first SODIMM;
a fourth portion to provide connectivity to a second gold finger on the second side of the first SODIMM;
a fifth portion to provide connectivity to a second gold finger on the first side of the second SODIMM; and
a sixth portion to provide connectivity to a second gold finger on the second side of the second SODIMM.

11. The apparatus of claim 10, wherein the first portion and the second portion are associated with DQ, CA, VSS, and VDD pins.

12. The apparatus of claim 10, wherein the third portion, fourth portion, fifth portion and the sixth portion are associated with CLK, CKE, ODT, and CS pins.

13. The SODIMM memory connector of claim 8 wherein the first SODIMM and the second SODIMM are both SODDR3 or SODDR4 memory modules.

14. An apparatus comprising:
a transmission line;
a motherboard comprising a via; and
a SODIMM memory connector coupled to the motherboard and in communication with the transmission line using the via, the SODIMM memory connector comprising:
a first socket to electrically couple a first SODIMM; and
a second socket to electrically couple a second SODIMM, where the first socket is disposed vertically adjacent to the second socket.

15. The apparatus of claim 14, wherein the SODIMM memory connector comprises:
a first portion to provide connectivity to a first gold finger on a first side of a first SODIMM and to provide connectivity to a first gold finger on a first side of a second SODIMM; and
a second portion to provide connectivity to a first gold finger on a second side of the first SODIMM and to provide connectivity to a first gold finger on the second side of the second SODIMM.

16. The apparatus of claim 15, wherein the SODIMM memory connector further comprises:
a third portion to provide connectivity to a second gold finger on the first side of the first SODIMM;
a fourth portion to provide connectivity to a second gold finger on the second side of the first SODIMM;
a fifth portion to provide connectivity to a second gold finger on the first side of the second SODIMM; and
a sixth portion to provide connectivity to a second gold finger on the second side of the second SODIMM.

17. The apparatus of claim 16, wherein the first portion and the second portion are associated with DQ, CA, VSS, and VDD pins.

18. The apparatus of claim 16, wherein the third portion, fourth portion, fifth portion and the sixth portion are associated with CLK, CKE, ODT, and CS pins.

19. The apparatus of claim 14 wherein the first SODIMM and the second SODIMM are SODDR3 memory modules.

20. The apparatus of claim 14 wherein the first SODIMM and the second SODIMM are SODDR4 memory modules.
